(19) United States
(12) Patent Application Publication
(10) Pub. No.: US 2023/0284398 A1
(43) Pub. Date: Sep. 7, 2023

(54) SYSTEM AND ANTI-SPLASH, ANTICORROSIVE ELECTRODE-PROTECTING DEVICE

(71) Applicant: Percy Danilo YÁÑEZ CASTAÑEDA, Antofagasta (CL)

(72) Inventor: Percy Danilo YÁÑEZ CASTAÑEDA, Antofagasta (CL)

(21) Appl. No.: 17/778,820

(22) PCT Filed: Nov. 20, 2020
(86) PCT No.: PCT/CL2020/050159

§ 371 Date: May 20, 2022

Related U.S. Application Data
(60) Provisional application No. 62/938,705, filed on Nov. 21, 2019.

(51) Int. Cl. H05K 5/00; H05K 5/02; H05K 13/00

(52) U.S. Cl. CPC H05K 5/0021; H05K 5/0004; H05K 5/0091; H05K 5/0209; H05K 5/0217; H05K 13/0007

(57) ABSTRACT

During the electrodeposition and electrorefining processes of metals, the electrodes undergo severe corrosion effects. A protective device and included system are proposed, wherein the electrode protective device solves the problem, given that its design and material preferably fireproof and anticorrosive, protect the electrodes. The design encompasses the entire exterior shape of the electrode support bar including the straight parts of the electrode plate that arise from the area of the support bars on both sides.

The present Application refers to a protective device for electrodes and a protective, anti-pitting and anticorrosive system comprising it wherein the protective system includes at least one protective device, preferably a protective device per electrode. Said protective device is preferably flame retardant thus avoiding pitting in the electrode plates which will make it easier for the cathodes to be harvested, to detach easily.

The protective device also prevents corrosion in the electrode support bars preventing their detachment, damage of the electrode and, consequently, its replacement thus achieving a significant reduction in production and maintenance costs.

### BACKGROUND

It is known that during the electrodeposition and electrorefining processes of metals the electrodes suffer severe corrosion effects, both in the support bars and in the plates that compose them as a result of the conditions of a high oxidizing medium caused by the acid mist and multiple factors that accelerate corrosion, such as the temperature of the electrodes and the rich electrolyte, the surface condition of the electrodes, the acid concentration of the electrolyte, the concentration of chlorides, the oxidation-reduction potential of the electrodes and other compounds that are formed. This generates various problems, such as the detachment of the electrode support bars from the plates, added to the corrosion located on the cathodic surface immediately above the electrolyte level of which line delimits the submerged section giving rise to pitting, wherein pitting makes it difficult for the cathodes to detach during harvesting and can be so deep that they pierce the cathode surface.

All this problem, whether the bars are detached from the supports, the cathodes sticking during the harvest due to pitting, or the electrode plates, both anodes and cathodes, deteriorate, increase production costs for maintenance or replacement of electrodes.

As an example, the global reaction of the cell process used in the copper electrowinning operation can be described.

$${\text{CuSO}}_{4} + {\text{H}}_{2} \text{O} \to \text{Cu} \left(\text{s}\right) + {\text{H}}_{2} {\text{SO}}_{4} \left(\text{aq}\right) + {\text{½O}}_{2} \left(\text{g}\right) \qquad \text{(A)}$$

In the lead anode the reaction that will take place on its surface releasing oxygen:

$${\text{H}}_{2} \text{O} \left(\text{l}\right) \to {\text{½O}}_{2} \left(\text{g}\right) + 2 {\text{H}}^{+} + 2 {\text{e}}^{\text{-}} \qquad \text{(B)}$$

At the cathode, the reaction that takes place on its surface is:

$${\text{Cu}}^{2 +} \left(\text{aq}\right) + {\text{2e}}^{\text{-}} \to \text{Cu} \left(\text{s}\right) \qquad \text{(C)}$$

In the copper electrowinning process, gaseous oxygen is generated on the surface of the anode as a result of the potential to which it is subjected, and which can be represented through equation (B). The development of the reaction will produce the saturation of the electrolyte by millions of bubbles generated on the anodic surface, which will rise through the solution to finally be released into the environment. The occurrence of this phenomenon will result in the suspension of highly corrosive micro-drops in air, called Acid Mist.

This highly corrosive acid mist, added to the existing conditions in the operation cause the formation of pitting on the surface of the cathode; what the device of the invention does is to facilitate the output of the millions of highly corrosive air bubbles and isolate the cathodic surface of the electrode plates from the corrosive effects of the acid mist, since it is not in direct contact with the surface of the electrodes on the cutting line (above the electrolyte level).

Currently, the electrodes are protected from corrosion with an anticorrosive paint, in some cases, and in others with an adhesive film, also anticorrosive. In both cases, the applied coating is effective for a period of 2 or 3 months, after this time, and due to the action of all the corrosive factors mentioned the paint protection peels off and/or the film peels off, so the protection loses effectiveness as the surfaces are again exposed to corrosion.

Another solution to combat corrosion is implemented at the factory, consisting of adding an additional wall of lead coating between 5 to 7 mm to the support bars of the lead anodes, so that the entire bar is thickened between the joint of the support bar with the anode plate; something similar is done in the stainless steel cathode wherein the support bar is completely covered with an additional stainless steel cover which is welded to the mother plate. This solution considerably increases production costs, and the protection of the support bar does not solve the problem of pitting in the area of the electrolyte level.

Therefore, the main problem that the present invention solves is to protect the electrodes against corrosion which causes pitting on the plates above the electrolyte level which causes the plates to be perforated or the cathodes to be harvested to stick to the mother plate, preventing its easy detachment.

In addition, another problem that the present invention solves, in combination with the previous one, is associated with the detachment of the support bars wherein corrosion causes their detachment from the electrode plates.

With the device and protection system, it is possible to significantly increase the useful life of the electrodes and increase the production of cathodes during operation.

### BRIEF DESCRIPTION OF THE INVENTION

As stated above, the existing systems do not protect the electrodes against corrosion, they only mitigate its effect, and the electrodes continue to have the aforementioned problems.

Against the above, the present invention proposes a protective device and a system comprising at least one protective device. Said protective device with an elongated body, preferably in one piece, surrounds the entire exterior shape of the electrode support bar and includes the straight parts of the electrode plate that arise from the support bar, on both sides, and may end on the cutting line that delimits the submerged section of the cell electrolyte level. Said elongated body may be a sheet preferably made of flame retardant, cut resistant and acid resistant material, and may be made of plastic material, synthetic rubber, elastomer, stainless steel, titanium, or a combination of them. As indicated, preferably, the elongated body covers and borders the entire electrode until reaching the electrolyte level cut-off line.

The elongated body protective device may incorporate reinforcements for self-tightening on the outer face, in the form of self-tightening pliers, which border the support bar together with the electrode plate up to the cutting line. It is also possible to install a toothed wedge type tightening system in some parts or sectors of the device or in its entirety along the protective device in the upper part of the same.

In addition, to protect the anticorrosive protective device installed on the anode, guide elements could be used in the form of guide cones on its surface, in order to help the centering and rapid descent of the cathodes with cutting edges.

### DESCRIPTION OF DRAWINGS

For a better explanation of the invention a description will be made in relation to the Figures of embodiments of the invention, where:

FIG. 1 shows an isometric view of an electrode protective device, according to a first embodiment, reinforced for self-tightening and installed on a cathode.

FIG. 2 shows an isometric view only of the electrode protective device of FIG. 1 reinforced for self-tightening and designed for cathodes.

FIG. 2a shows three views of the electrode protective device of FIG. 1 reinforced for self-tightening and designed for cathodes.

FIG. 2b shows a front view of the electrode protective device of FIG. 1 reinforced for self-tightening and installed on a cathode.

FIG. 3 shows an isometric view of the electrode protective devices of FIG. 1 reinforced for self-tightening and installed on a cathode assembly.

FIG. 4 shows an isometric view of an electrode protective device, according to the first embodiment, reinforced for self-tightening and installed on an anode.

FIG. 5 shows an isometric view only of the electrode protective device of FIG. 4 reinforced for self-tightening and designed for anodes.

FIG. 5a shows three main views of the electrode protective device of FIG. 4 reinforced for self-tightening and designed for anodes.

FIG. 5b shows a front view of the electrode protective device of FIG. 4 reinforced for self-tightening and installed on an anode.

FIG. 6 shows an isometric view of the electrode protective devices of FIG. 4 reinforced for self-tightening and installed on an anode assembly.

FIG. 7 shows an isometric view of an electrode protective device according to a second embodiment without reinforcements and installed on a cathode.

FIG. 8 shows an isometric view only of the electrode protective device of FIG. 7 without reinforcements and designed for cathodes.

FIG. 8a shows three main views of the electrode protective device of FIG. 7 without reinforcements and designed for cathodes.

FIG. 8b shows a front view of the electrode protective device of FIG. 7 without reinforcements and installed on a cathode.

FIG. 9 shows an isometric view of the electrode protective devices of FIG. 7 without reinforcements and installed on a cathode assembly.

FIG. 10 shows an isometric view of an electrode protective device according to the second embodiment without reinforcements and installed on an anode.

FIG. 11 shows an isometric view only of the electrode protective device of FIG. 8 without reinforcements and designed for anodes.

FIG. 11a shows three main views of the electrode protective device of FIG. 8 without reinforcements and designed for anodes.

FIG. 11b shows a front view of the electrode protective device of FIG. 8 without reinforcements and installed on an anode.

FIG. 12 shows an isometric view of the electrode protective devices of FIG. 8 without reinforcements and installed on an anode assembly.

FIG. 13 shows an isometric view of a sector of an electrode protective device, according to a third embodiment, without reinforcement showing a toothed wedge-type tightening system in the upper part of the device.

FIG. 13a shows a complete isometric view of the electrode protective device of FIG. 13 showing on the top of the device a toothed wedge-type tightening system.

FIG. 14 shows an isometric view of a sector of an electrode protective device, according to a fourth embodiment, reinforced for self-tightening which shows a toothed wedge-type tightening system on the top of the device.

FIG. 15 shows an isometric view of an electrode protective device according, to a fifth embodiment, installed on an anode, reinforced for self-tightening, showing in the upper part of the device an enlarged view of the toothed wedge-type tightening system in the form of self-tightening pliers.

FIG. 16 shows an isometric view of an electrode protective device, according to the fifth embodiment, installed on a cathode reinforced for self-tightening, showing in the upper part of the device an enlarged view of the toothed wedge-type tightening system in the form of self-tightening pliers.

### DETAILED DESCRIPTION OF THE EMBODIMENTS OF THE INVENTION

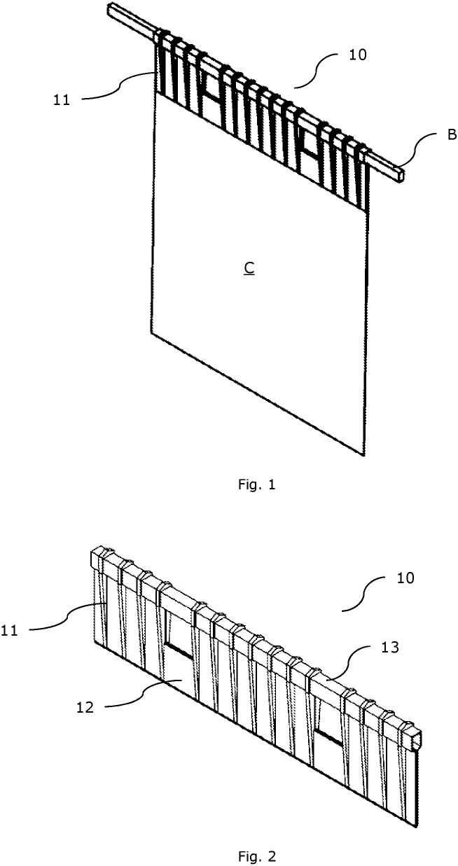

FIG. 1 shows a diagram of a protective device (10) according to a first embodiment of the invention comprising self-tightening reinforcements (11), in this case, configured in the form of vertical ribs of the self-tightening clamp type, which are arranged surrounding the entire upper portion of the electrode when the protective device (10) is installed on the same. In this case, FIG. 1 shows the protective device (10) installed on a cathode (C) covering an upper portion of said cathode and part of its support bar (B). According to a preferred embodiment, the upper portion of the cathode, which is covered by the protective device (10), encompasses the entire portion of the cathode that in operation is above the electrolyte level, that is, that portion in direct contact with the acid mist that is generated inside the cells.

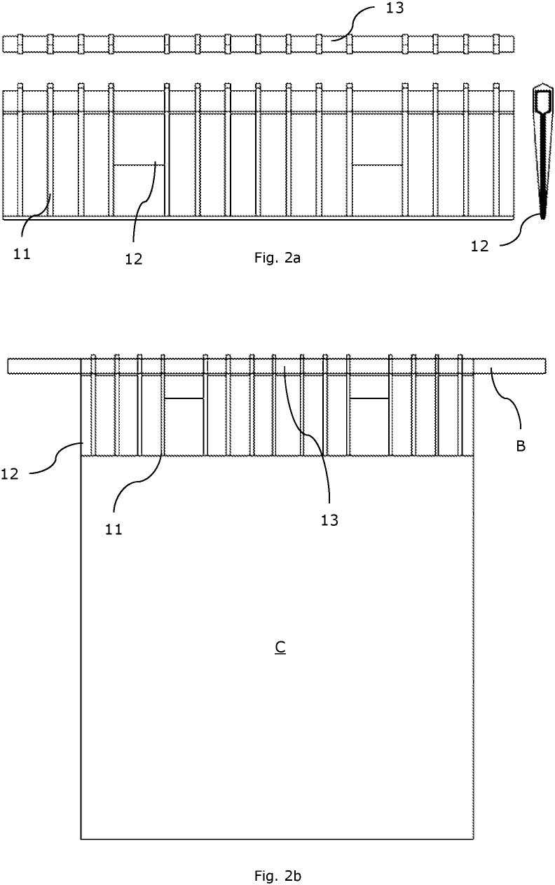

FIG. 2 shows a diagram of the protective device (10) by itself where it can be seen that it comprises lower portions (12) and an upper portion (13 wherein the lower portions (12) are configured to surround, from above, at least part of the cathode plate (C) and wherein the upper portion (13) is configured to surround, from above, the support bar (B).

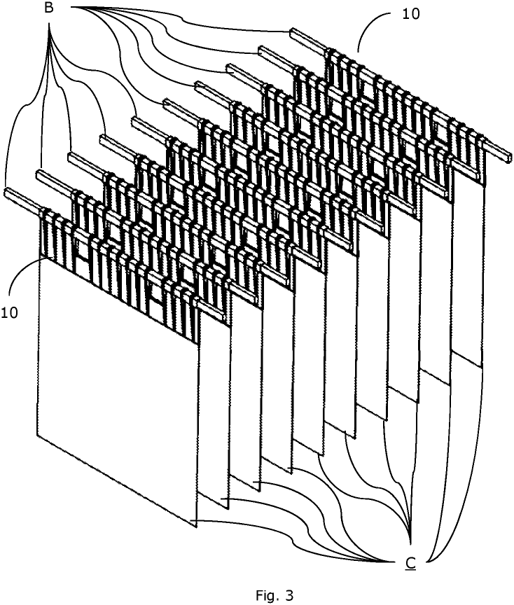

FIG. 2a shows three views of the protective device (10) identifying its front, top and side features. Through these three views it is possible to see that the protective device (10) comprises self-tightening reinforcements (11) that function as gripping pliers when the protective device is installed on an electrode. In effect, the installation of the protective device comprises separating both lower portions (12) generating an interior space that allows the protective device (10) to be installed on the electrode plate, sliding, or inserting the support bar inside the upper portion (13). Then, the self-tightening reinforcements (11) allow to maintain the rigidity of the protective device (10) keeping it fixed on the electrode plate. FIG. 2b shows the protective device (10) installed on a cathode (C) as in FIG. 1. Then, FIG. 3 shows a series of cathodes (C) comprising the protective device (10).

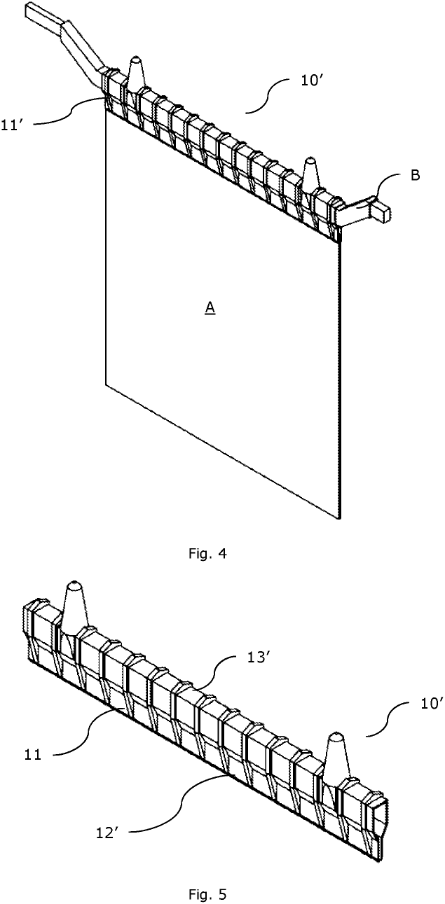

On the other hand, FIG. 4 shows a protective device (10′), according to the first embodiment, comprising self-tightening reinforcements (11′), in this case configured in the form of vertical ribs of the self-tightening clamp type which are arranged surrounding the entire upper portion of the electrode when the protective device (10′) is installed on the same. In this case, FIG. 1 shows the protective device (10′) installed on an anode (A) covering an upper portion of said anode and part of its support bar (B). According to a preferred embodiment, the upper portion of the anode, which is covered by the protective device (10′), encompasses the entire portion of the anode that in operation, is above the electrolyte level, that is, that portion in direct contact with the acid mist that is generated inside the cells.

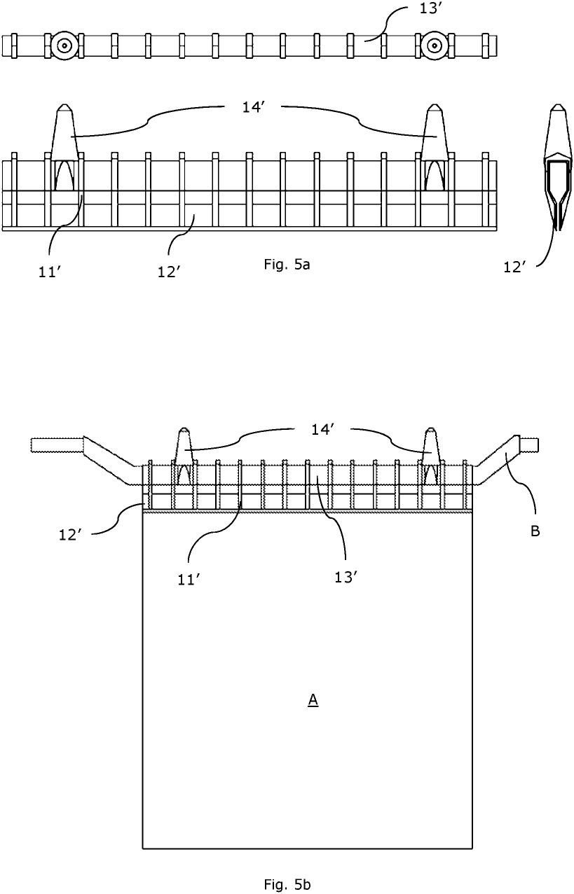

FIG. 5 shows a diagram of the protective device (10′) by itself, where it can be seen that it comprises lower portions (12′) and an upper portion (13′), wherein the lower portions (12′) are configured to surround, from above, at least part of the anode plate (A), and wherein the upper portion (13′) is configured to surround, from above, the support bar (B). In addition, in FIG. 5 it can be seen that the protective device (10′) comprises upper guide elements (14′) configured to guide the cathodes during the entry/removal operations to/from the electrolytic cell, wherein said upper guides elements (14′) have a conical shape and a rounded surface to prevent the lower edge of adjacent electrodes, in this case cathodes, from getting stuck during said entry/removal operations.

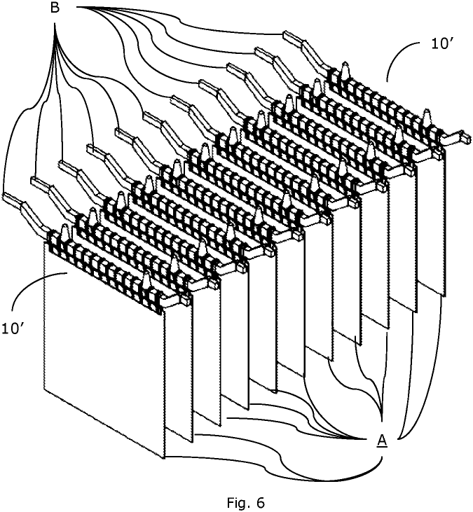

FIG. 5a shows three views of the protective device (10′) identifying its front, top and side features. Through these three views it is possible to see that the protective device (10′) comprises self-tightening reinforcements (11′) that function as gripping pliers, as in the previous case. In effect, the installation of the protective device comprises separating both lower portions (12′) generating an interior space that allows the protective device (10′) to be installed on the electrode plate, sliding, or inserting the support bar inside the top portion (13′). Then, the self-tightening reinforcements (11′) allow to maintain the rigidity of the protective device (10′) keeping it fixed on the electrode plate. FIG. 5b shows the protective device (10′) installed on an anode (A), as in FIG. 4. Then, FIG. 6 shows a series of anodes (A) comprising the protective device (10′).

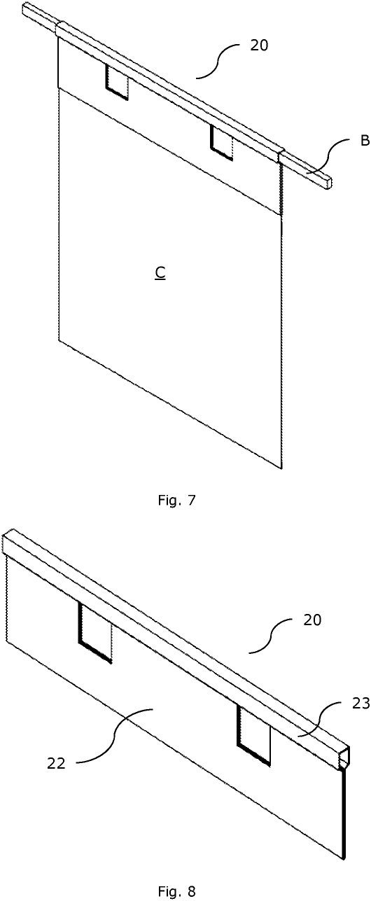

A second embodiment of the invention is shown in FIG. 7, which shows a protective device (20) according to the second embodiment with a simple configuration without reinforcements for self-tightening. In this case, FIG. 7 shows the protective device (20) installed on a cathode (C) covering an upper portion of said cathode and part of its support bar (B). According to a preferred embodiment, the upper portion of the cathode, which is covered by the protective device (20), encompasses the entire portion of the cathode that in operation is above the electrolyte level, that is, that portion in direct contact with the acid mist that is generated inside the cells.

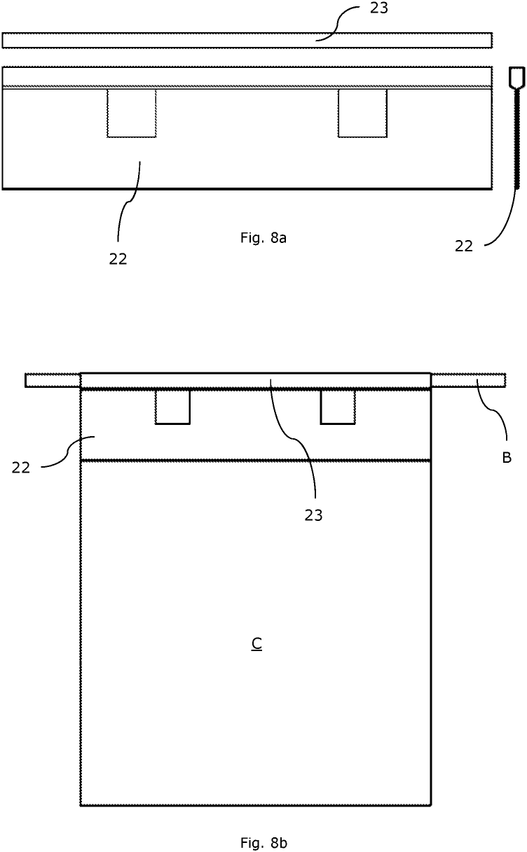

FIG. 8 shows a diagram of the protective device (20) by itself where it can be seen that it comprises lower portions (22) and an upper portion (23), wherein the lower portions (22) are configured to surround, from above, at least part of the cathode plate (C), and wherein the upper portion (23) is configured to surround, from above, the support bar (B).

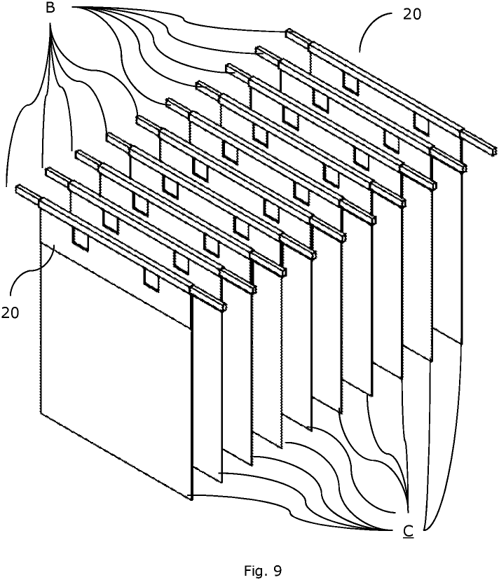

FIG. 8a shows three views of the protective device (20) identifying its front, top and side features. By means of said three views it is possible to appreciate that the protective device (20) has a simple and smooth appearance without reinforcements for self-tightening. In this case, the installation of the protective device comprises separating both lower portions (22), generating an interior space that allows the protective device (20) to be installed on the electrode plate, sliding, or inserting the support bar inside the upper portion. (23). Then, the same rigidity of the material of the protective device (20) prevents its deformation during installation keeping it fixed on the electrode plate. FIG. 8b shows the protective device (20) installed on a cathode (C), as in FIG. 7. Then, FIG. 9 shows a series of cathodes (C) comprising the protective device (20).

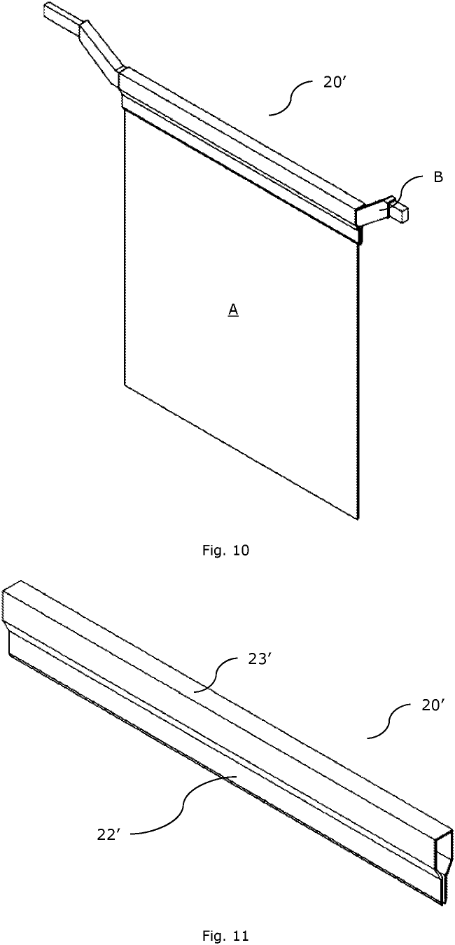

On the other hand, FIG. 10 shows a protective device (20′) according to the second embodiment without reinforcements for self-tightening. In this case, FIG. 10 shows the protective device (20′) installed on an anode (A) covering an upper portion of said anode and part of its support bar (B). According to a preferred embodiment, the upper portion of the anode, which is covered by the protective device (20′), encompasses the entire portion of the anode that in operation is above the electrolyte level, that is, that portion in direct contact with the acid mist that is generated inside the cells.

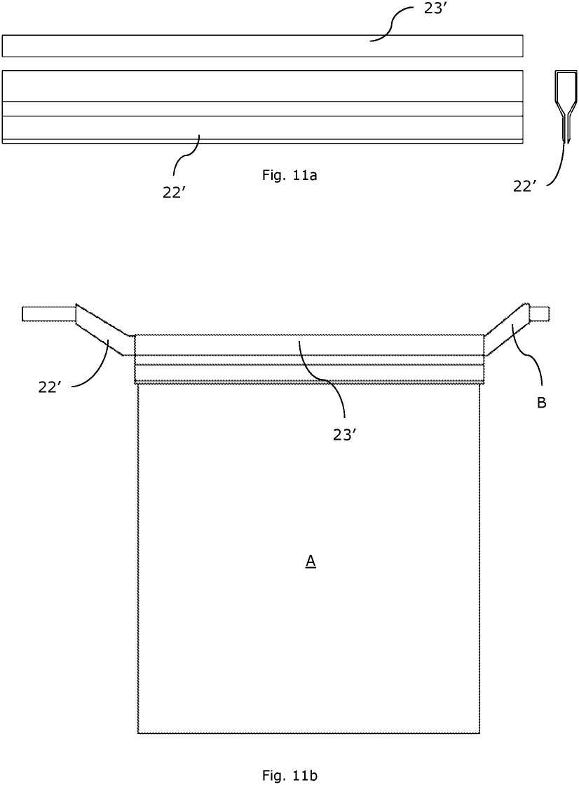

FIG. 11 shows a diagram of the protective device (20′) by itself where it can be seen that it comprises lower portions (22′) and an upper portion (23′), wherein the lower portions (22′) are configured to surround, from above, at least part of the anode plate (A), and wherein the upper portion (23′) is configured to surround, from above, the support bar (B). In addition, in FIG. 11 it can be seen that the protective device (20′) lacks upper guide elements, simplifying its construction.

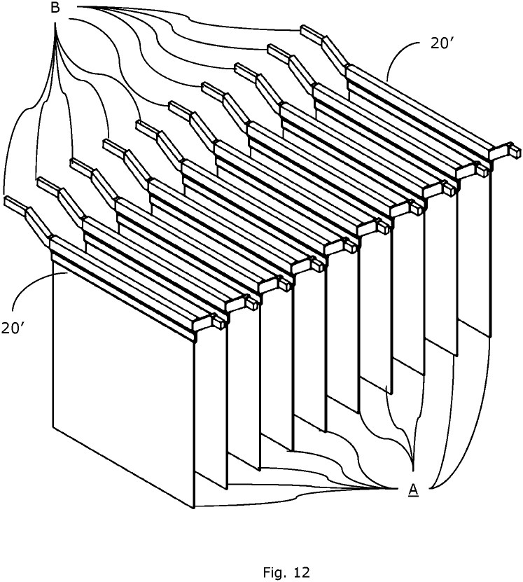

FIG. 11a shows three views of the protective device (20′) identifying its front, top and side features. Through these three views it is possible to see that the protective device (20′) lacks reinforcements for self-tightening. In this case, the installation of the protective device comprises separating both lower portions (22′) generating an interior space that allows the protective device (20′) to be installed on the electrode plate, sliding, or inserting the support bar inside the upper portion (23′). Then, the same rigidity of the material of the protective device (20′) prevents its deformation during installation keeping it fixed on the electrode plate. FIG. 11b shows the protective device (20′) installed on an anode (A), as in FIG. 10. Then, FIG. 12 shows a series of anodes (A) comprising the protective device (20′).

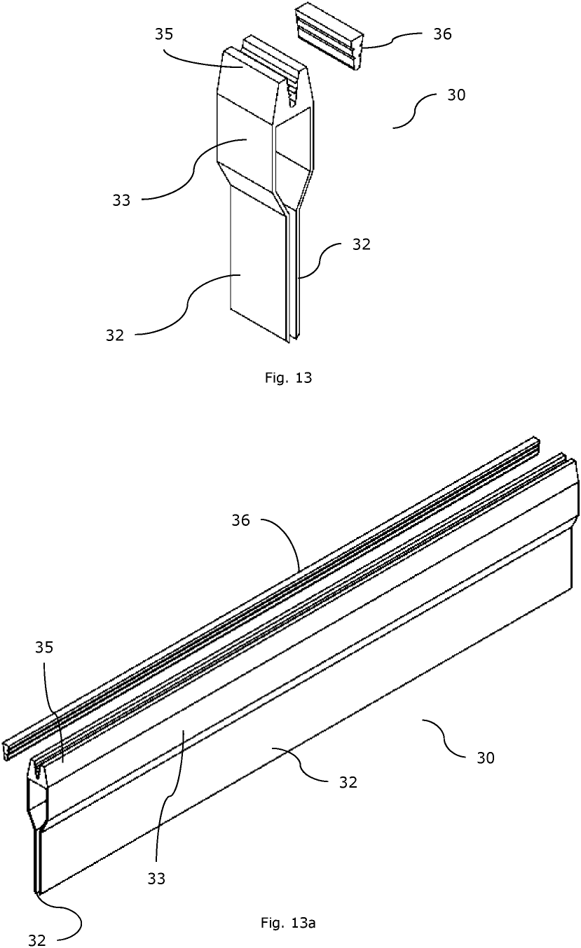

A third embodiment of the invention is shown in FIGS. 13 and 13a, where it is possible to see a protective device (30) comprising on the upper portion (33), a toothed wedge-type tightening system. Said clamping system, which acts as a clamp, is formed by a toothed opening or groove (35) which is complemented by a toothed wedge element (36) so that, when the wedge element (36) is inserted into the groove (35) being fixed by the teeth, a clamping force is exerted on the lower portions (32) of the protective device (30) holding them together. Said tightening force is sufficient, so that, once the protective device is installed on the electrode it is fixed to the electrode, preventing, or hindering its release. Then, to release the protective device (30) from the electrode the wedge element (36) must be removed. According to FIG. 13a, the wedge-type tightening system can extend over the entire length of the protective device (30).

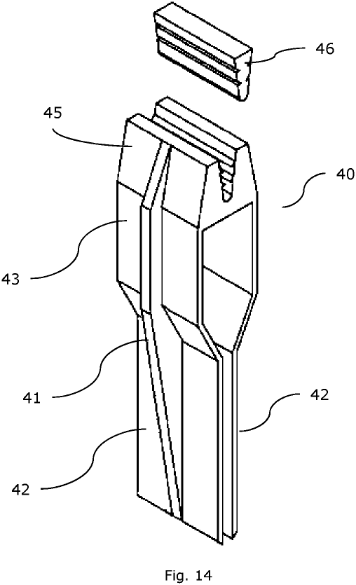

Although in FIGS. 13 and 13a the protective device (30) is shown with a toothed wedge-type tightening system without another type of reinforcement, a fourth embodiment of the invention comprises that said toothed wedge-type tightening system is implemented in a protective device (40) with reinforcements for self-tightening (41), such as the one shown in FIG. 14. Indeed, in FIG. 14 a portion of the protective device (40) is shown with reinforcements for self-tightening (41), wherein the upper portion (43) comprises a groove (45) arranged to receive the wedge element (46). In this case, it can be seen that the tightening force exerted on the lower portions (42) is transmitted from the groove (45) and through the self-tightening reinforcements (41), improving the fixation of the protective device (40) on the electrode plate.

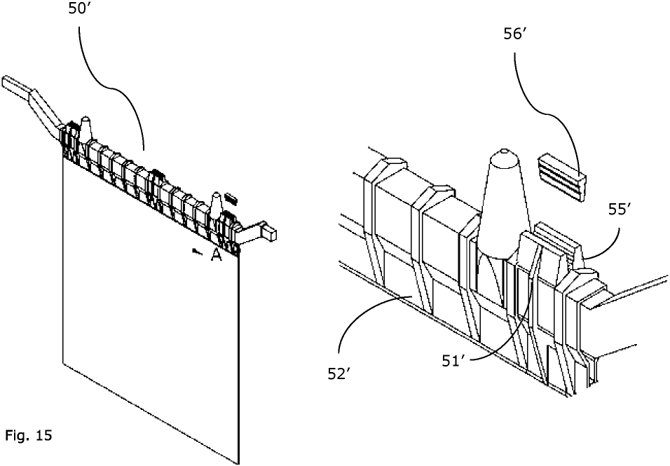

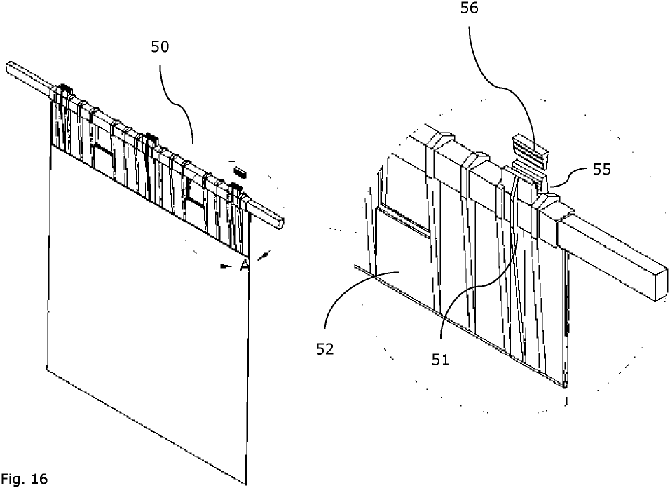

Similarly, FIGS. 15 and 16 show protective devices (50, 50′) according to a fifth embodiment based on the fourth embodiment, wherein self-tightening reinforcements (51, 51′) with toothed wedge-type tightening systems are implemented, as in the FIG. 14, but arranged in different sectors along each protective device (50, 50′) particularly towards the center and towards the ends of each device. In this way, it is possible to apply a uniform tightening force in the extension of the protective device. Furthermore, FIGS. 15 and 16 show a detail of one of the toothed wedge-type tightening systems appreciating its clamp-type configuration, wherein the groove (55, 55′) cooperates with the wedge-type element (56, 56′) to transmit the tightening force towards the protective device (50, 50′) particularly towards its lower portions (52, 52′).

Finally, the invention comprises an electrode protection system formed by at least two electrode protective devices, wherein a first protective device is installed on a cathode and a second protective device is installed on an anode. For example, the electrode protector system can be configured by combining the cathode and anode arrangements shown in FIGS. 3 and 6 or 9 and 12 forming a series of adjacent electrodes that comprise the protective device in its upper portion surrounding the support bar and at least part of each electrode, preferably at least the part exposed to the acid mist, on the electrolyte level.

1. An electrode protective device, comprising an elongated body with an upper portion and lower portions, wherein the upper portion wraps the entire outer shape of the electrode support bar, and wherein the lower portions wrap the straight parts of the electrode plate arising from the support bar on both sides.

2. The device according to claim 1, wherein the elongated body with the upper and lower portions surrounds the entire outer shape of the electrode support bar including the straight parts of the electrode plate that arise from the support bar, on both sides, so that the lower portions extend reaching the electrolyte level line in a cell.

3. The device according to claim 1, wherein the elongated body with the upper and lower portions surrounds the entire outer shape of the electrode support bar including only a portion of the straight parts of the electrode plate, on both sides, so that the lower portions extend without reaching the electrolyte level line.

4. The device according to claim 1, wherein the device is installed on electrodes, preferably lead or titanium anodes and stainless steel or titanium cathodes.

5. The device according to claim 1, wherein the elongated body is in one piece.

6. The device according to claim 1, wherein the elongated body is made of plastic, synthetic rubber, elastomers, stainless steel, titanium, or a combination of them, or other material that is flame retardant, cutting resistant, and acid resistant.

7. The device according to claim 1, wherein the device comprises on the upper portion, two or more guide elements, preferably conical.

8. The device according to claim 1, wherein the elongated body comprises reinforcements for self-tightening, in the form of self-tightening pliers, which surround the support bar together with the electrode plate on both sides.

9. The device according to claim 1, wherein, in some sectors of the upper portion, a toothed wedge-type tightening system is arranged.

10. The device according to claim 1, wherein a toothed wedge-type tightening system is arranged throughout the upper portion.

11. The device according to claim 1, wherein, in some sectors of the upper portion, when the protective device includes self-tightening reinforcements, the tightening is complemented with a toothed wedge-type tightening system.

12. The device according to claim 1, wherein, in the entire upper portion, when the protective device includes self-tightening reinforcements, the tightening is complemented with a toothed wedge-type tightening system.

13. The device according to claim 9, wherein the toothed wedge-type tightening system comprises a groove, or a toothed groove, and a wedge element, or a toothed wedge element, wherein the wedge element is configured to be inserted into the groove.

14. An electrode protection system, comprising at least two electrode protective devices according to claim 1, wherein a first protective device is installed on a cathode and a second protective device is installed on an anode.
